(19) United States
(12) Patent Application Publication
(10) Pub. No.: US 2017/0020031 A1
(43) Pub. Date: Jan. 19, 2017

(54) Fan Carrier Apparatus

(71) Applicant: COMPAL BROADBAND NETWORKS INC., Taipei City (TW)

(72) Inventors: Chung-Ming Pan, Hsinchu County (TW); Chiang-Chang Wu, Hsinchu County (TW); Cheng-Shan Lin, Hsinchu County (TW)

(21) Appl. No.: 15/140,487

(22) Filed: Apr. 28, 2016

Related U.S. Application Data
(60) Provisional application No. 62/193,099, filed on Jul. 16, 2015.

(30) Foreign Application Priority Data
Nov. 19, 2015 (TW) 104218567

(51) Int. Cl. H05K 7/20; H05K 1/02

(52) U.S. Cl. CPC H05K 7/20172; H05K 1/0203

(57) ABSTRACT

A fan carrier apparatus for an electronic apparatus includes a base, at least one fan and a current-conduction module. The base includes at least one opening. The at least one fan is disposed at the at least one opening of the base. The current-conduction module is disposed on the base and includes at least one hole. Accordingly, an air corresponding to the at least one fan penetrates the at least one hole to assist heat dissipation of the electronic apparatus.

### CROSS REFERENCE TO RELATED APPLICATIONS

This application claims the benefit of both U.S. Provisional Application No. 62/193,099, filed on Jul. 16, 2015 and entitled “The structure design of new product”, the contents of which are incorporated herein.

### BACKGROUND OF THE INVENTION

1. Field of the Invention

The present invention relates to a fan carrier apparatus for an electronic apparatus, and more particularly, to a fan carrier apparatus for efficiently improving heat dissipation of the electronic apparatus which comprises a plurality of electronic elements being vertically disposed.

2. Description of the Prior Art

For the sake of comfortable operations for users and fitting different living/working circumstances, exterior appearances of many electronic apparatuses are designed to approach a simplified structure. Under such circumstances, it has become an important issue to provide a well-designed heat-dissipation apparatus to maintain efficient operations and considerate protections for the electronic apparatuses.

### SUMMARY OF THE INVENTION

Therefore, the primary objective of the present invention is to provide a fan carrier apparatus for efficiently elevating heat dissipation of an electronic apparatus.

The present invention discloses a fan carrier apparatus for an electronic apparatus. The fan carrier apparatus comprises a base, comprising at least one opening; at least one fan, disposed at the at least one opening of the base; and a current-conduction module, disposed on the base and comprising at least one hole, such that an air corresponding to the at least one fan penetrates the at least one hole to assist heat dissipation of the electronic apparatus.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates an entire schematic diagram of an electronic apparatus according to an embodiment of the invention.

FIG. 2 illustrates a local schematic diagram of a fan carrier apparatus according to an embodiment of the invention.

FIG. 3 illustrates an exploded schematic diagram of a fan carrier apparatus according to an embodiment of the invention.

FIG. 4 and FIG. 5 illustrate perspective schematic diagrams of electronic apparatuses according to different embodiments of the invention.

### DETAILED DESCRIPTION

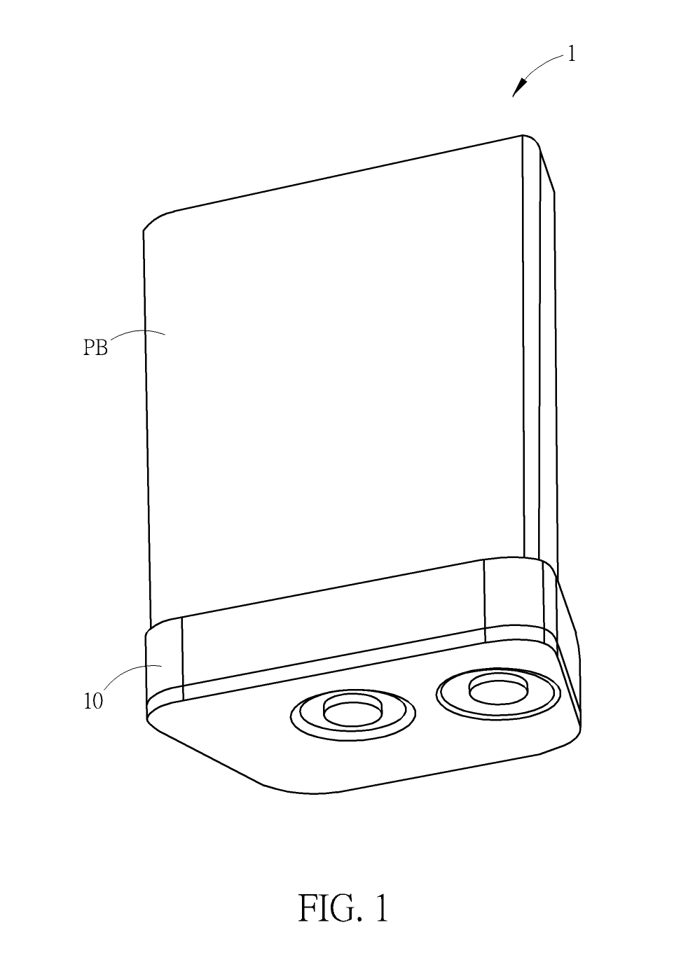

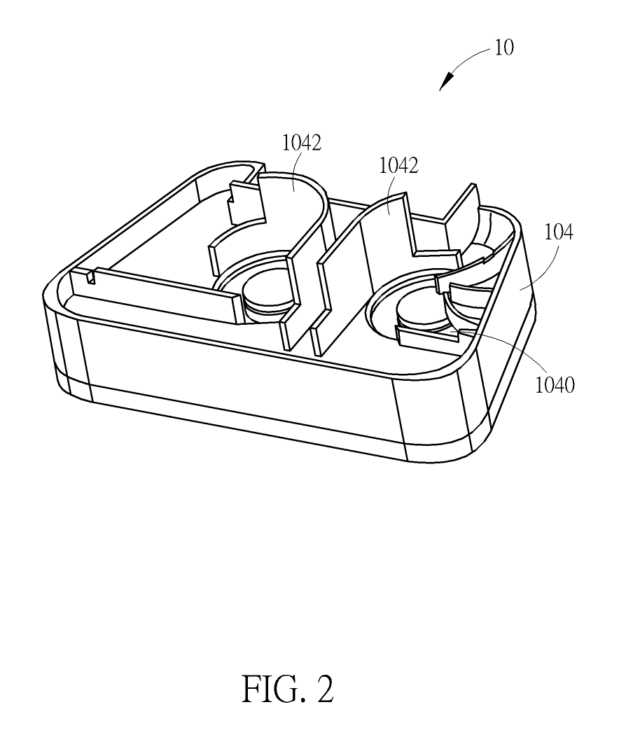

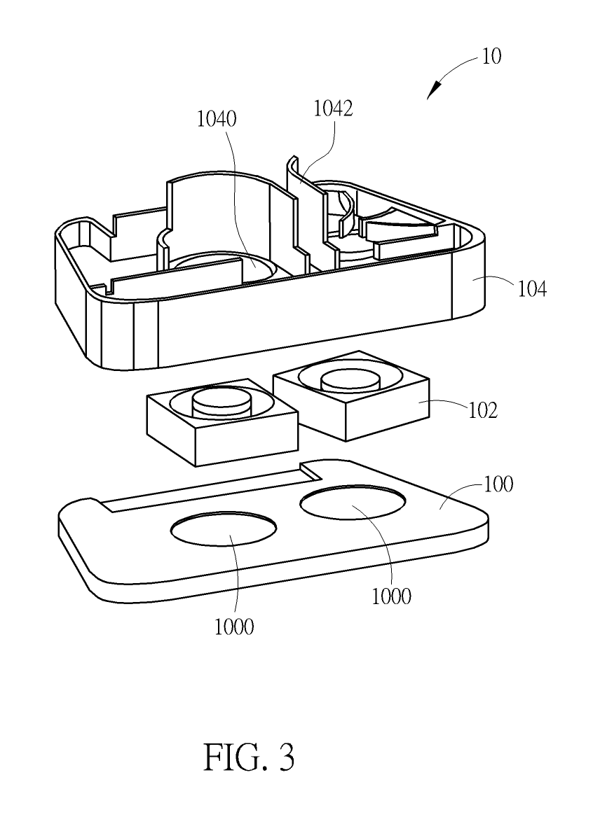

Please refer to FIG. 1 to FIG. 3, wherein FIG. 1 illustrates an entire schematic diagram of an electronic apparatus 1 according to an embodiment of the invention, FIG. 2 illustrates a local schematic diagram of a fan carrier apparatus 10 of the electronic apparatus 1 shown in FIG. 1, and FIG. 3 illustrates an exploded schematic diagram of a fan carrier apparatus 10 of the electronic apparatus 1 shown in FIG. 1.

As shown in FIG. 1, the electronic apparatus 1 of the embodiment comprises a plurality of electronic elements PB and a fan carrier apparatus 10. Preferably, the plurality of electronic elements PB are printed circuit boards (PCBs) to be vertically surrounded onto an external area of the fan carrier apparatus 10 (i.e. being disposed at an edge of a base of the fan carrier apparatus 10). Under such circumstances, the plurality of PCBs PB are closely surrounded to each other to form a column-shape wind tunnel, and the fan carrier apparatus is located at one terminal of the column-shape wind tunnel. When the electronic apparatus 1 is operated to generate heat by the plurality of PCBs PB, at least one fan of the fan carrier apparatus 10 can cooperate with the column-shape wind tunnel to efficiently elevating heat dissipation of the electronic apparatus 1.

In details, as shown in FIG. 2 and FIG. 3, the fan carrier apparatus 10 of the embodiment comprises a base 100, two fans 102 and a current-conduction module 104. The base 100 of the embodiment comprises a plurality of openings 1000, the two fans 102 of the embodiment are disposed at two of the plurality of openings 1000, i.e. the structure of internal rotation vanes of the fan 102 corresponds to the size of the opening 1000, such that the fan 102 is operated to inhale or exhale gas via the opening 1000, so as to dissipate the heat inside the electronic apparatus 1. Certainly, the number of the fan of the embodiment is illustrated for demonstration, and according to different operations or power requirements of the electronic apparatus 1, the number of the fan can be adaptively modified, which is also within the scope of the invention. Besides, the current-conduction module 104 is disposed on the base 100, and comprises at least one hole 1040 to map a location of the fan 102, such that an air corresponding to the fan 102 can penetrate the at least one hole 1040 to assist the heat dissipation of the electronic apparatus 1. Further, a configuration number and a relative position of the opening 1000 or the hole 1040 in the embodiment are illustrated for demonstration, and the a projection plane of opening 1000 can overlap another projection plane of the hole 1040, such that the configuration position of opening 1000 or the hole 1040 can cooperate with the configuration number/position of the fan 102 for assisting the circulation of the internal gas inside the electronic apparatus 1, which is also within the scope of the invention.

Furthermore, the current-conduction module 104 of the embodiment further comprises at least one air-conduction vane 1042 to be disposed near the hole 1040 for conducting a circulating direction of the air corresponding to the fan 102. In other words, the air-conduction vane 1042 of the embodiment forms a circular board with a height which can be adaptively adjusted rather than being the same in every parts of the circular board. Accordingly, the circular board of the air-conduction vane 1042 can prevent the user from accidentally inserting an object into the hole 1040 while installing/disassembling the fan carrier board 10, and the circular board can also help vertically conduct the air flowing from the bottom to the top, such that the air inside the electronic apparatus 1 will not arbitrarily form local turbulence floating inside the column-shape wind tunnel, so as to improve the heat dissipation of the electronic apparatus 1.

Certainly, a housing of the fan carrier apparatus 10 of the embodiment further comprises at least one heat-dissipation hole (not shown in the hole), and a position of the heat-dissipation hole can be adaptively adjusted according to different composition elements of the electronic apparatus 1. Accordingly, when the air corresponding to the fan 12 flows from the bottom to the top with the assistance of the circular board of the air-conduction vane 1042, the fan 102 can inhale an external gas (i.e. an air having a lower temperature) via the opening 1000 and exhale an internal gas (i.e. an air having a higher temperature) of the fan carrier apparatus 10 via the at least one heat-dissipation hole. Under such circumstances, since a flow amount of the external gas inhaled via the opening 1000 equals another flow amount of the internal gas exhaled via the one heat-dissipation hole, an air convection of the embodiment also accelerates a heat dissipation rate of the electronic apparatus 1.

Besides, since a hot air has a lower density to result in floating upward, the embodiment of the invention provides the scheme that the fan carrier apparatus 10 is disposed at the bottom of the electronic apparatus 1, such that the opening 1000 locating at the bottom can cooperate with the fan 102 to inhale the external gas and the column-shape wind tunnel of the electronic apparatus 1 can be configured to upward dissipate the heat inside the electronic apparatus 1. Certainly, the fan carrier apparatus 10 of the embodiment can also be disposed at a side or a top of the housing of the electronic apparatus 1 to keep the column-shape wind tunnel for generating a rapid air flow, which is also within the scope of the invention. In other embodiments, those skilled in the art can also install at least one assistance fan to be disposed at a top or a side of the housing of the electronic apparatus 1, so as to replace (or cooperate with) the original fan 102 disposed at the bottom of the electronic apparatus 1, so as to have the internal gas to be exhaled outside the electronic apparatus with a faster rate, which is also within the scope of the invention.

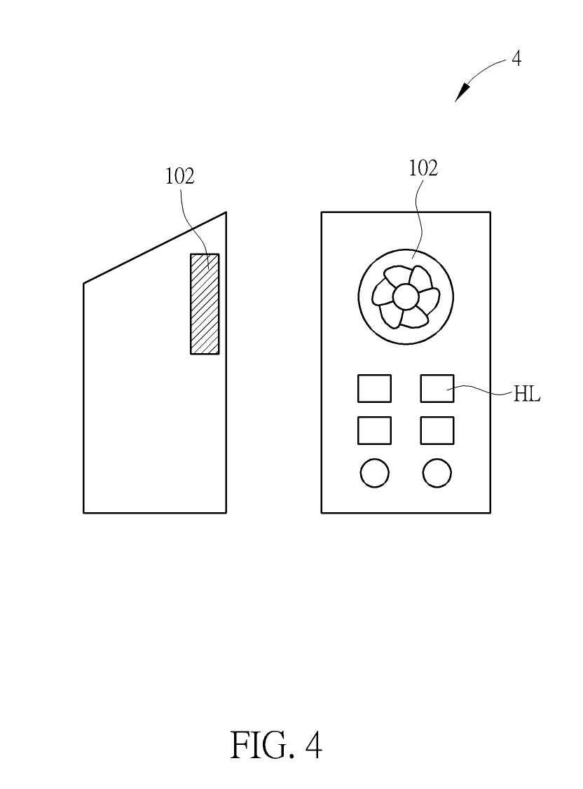

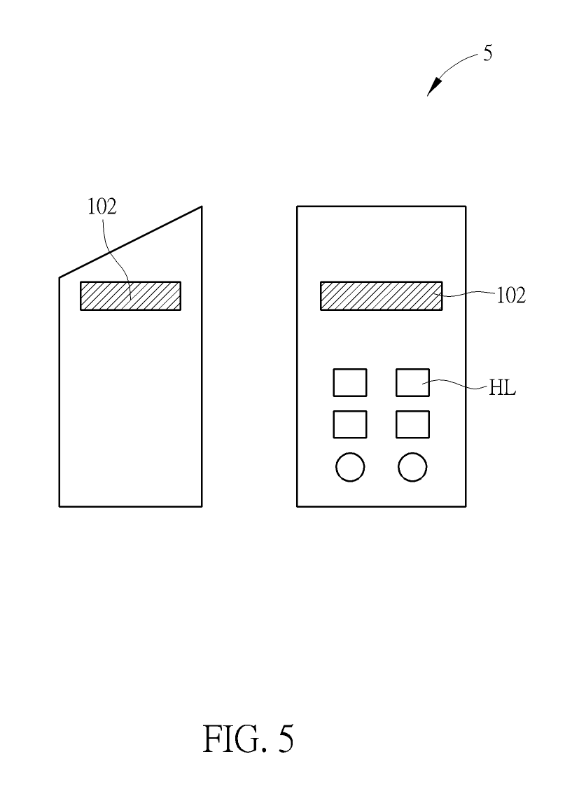

For example, please refer to FIG. 4 and FIG. 5, wherein FIG. 4 and FIG. 5 illustrate perspective schematic diagrams of electronic apparatuses 4 and 5 according to different embodiments of the invention. As shown in FIG. 4, the electronic apparatus 4 has the fan 102 to be disposed to at least one side of the housing, and a heat-dissipation hole or a circulation hole HL is also disposed on the housing of the electronic apparatus 4, such that the fan 102 can be operated to rapidly expel the internal gas with such an rapid air flow. In addition, as shown in FIG. 5, the electronic apparatus 5 has the fan 102 to be disposed at the top of the electronic apparatus 5, and another heat-dissipation hole or another circulation hole HL is also disposed on the housing of the electronic apparatus 5, such that the fan 102 can be operated to rapidly expel the internal gas with such a efficient heat dissipation. Certainly, the configuration number or the relative position of the fan, the heat-dissipation hole or the circulation hole mentioned above is demonstrated for illustration, and those skilled in the art can adaptively adjust or modify the configuration number or the relative position of the fan, the heat-dissipation hole or the circulation hole according to different requirements for approaching the best heat dissipation of the electronic apparatus, which is also within the scope of the invention.

In summary, the embodiments of the invention provide a fan carrier apparatus for an electronic apparatus, wherein the electronic apparatus has the structural designs, e.g. the column-shape wind tunnel and the current-conduction module, to form an upward air flow by the blowing of the fan, so as to rapidly dissipate the heat generated by the electronic apparatus. Also, the embodiments can utilize different number of the assistance fan(s), such that the heat dissipation rate of the embodiment can be adaptively adjusted under different operations of the electronic apparatus.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A fan carrier apparatus for an electronic apparatus, the fan carrier apparatus comprising:
a base, comprising at least one opening;
at least one fan, disposed at the at least one opening of the base; and
a current-conduction module, disposed on the base and comprising at least one hole, such that an air corresponding to the at least one fan penetrates the at least one hole to assist heat dissipation of the electronic apparatus.

2. The fan carrier apparatus of claim 1, wherein the current-conduction module further comprises at least one air-conduction vane to be disposed near the hole for conducting a circulating direction of the air corresponding to the at least one fan.

3. The fan carrier apparatus of claim 2, wherein the electronic apparatus comprises a plurality of electronic elements, each electronic element is vertically disposed at an edge of the base and generates heat, and the air corresponding to the at least one fan assists to dissipate the heat generated by the plurality of electronic elements.

4. The fan carrier apparatus of claim 3, wherein a housing of the electronic apparatus further comprises at least one heat-dissipation hole, and the fan is operated to inhale an external gas via the at least one opening and to exhale an internal gas via the at least one heat-dissipation hole, so as to assist the heat dissipation of the plurality of electronic elements.

5. The fan carrier apparatus of claim 3, wherein the plurality of electronic elements are a plurality of printed circuit boards (PCBs), and the plurality of PCBs are disposed to surround the fan carrier apparatus.

6. The fan carrier apparatus of claim 1, further comprising an assistance fan, disposed at a top or a side of the electronic apparatus to exhale an internal gas inside the electronic apparatus, and cooperating with at least one heat-dissipation hole of a housing of the electronic apparatus to form a circulation of the internal gas.
